(19) United States
(12) Patent Application Publication
(10) Pub. No.: US 2025/0141477 A1
(43) Pub. Date: May 1, 2025

(54) COMMON LOCAL OSCILLATOR CHIP, CASCADING STRUCTURE AND WORKING METHOD

(71) Applicant: Airtouch Intelligent Technology (Shanghai) Co., Ltd., Shanghai (CN)

(72) Inventors: Shuiyang LIN, Shanghai (CN); Ying SONG, Shanghai (CN); Keji CUI, Shanghai (CN)

(73) Assignee: Airtouch Intelligent Technology (Shanghai) Co., Ltd., Shanghai (CN)

(21) Appl. No.: 18/925,064

(22) Filed: Oct. 24, 2024

(30) Foreign Application Priority Data
Oct. 25, 2023 (CN) 2023113952577

(51) Int. Cl. H04B 1/04; H04Q 11/02

(52) U.S. Cl. CPC H04B 1/04; H04Q 11/02; H04Q 2213/064

(57) ABSTRACT

A common local oscillator chip, cascading structure, and method; the common local oscillator chip includes a local oscillator module, driving module, multiplexing matching network, local oscillator selection module, output matching network, and multiplexing transmission port. The local oscillator module provides an internal local oscillator signal; the driving module is connected to the local oscillator module, transmits the internal local oscillator signal when activated; the multiplexing matching network is connected to the driving module, outputs the internal local oscillator signal through the multiplexing transmission port, or receives an external local oscillator signal through the multiplexing transmission ports; the local oscillator selection module is connected to the local oscillator module and the multiplexing matching network, the local oscillator selection module is configured to select one of the internal local oscillator signal and external local oscillator signal, the chip local oscillator signal is generated through the output matching.

### FIELD OF TECHNOLOGY

The present disclosure belongs to the field of integrated circuit design, in particular it relates to a common local oscillator chip, a cascading structure and a working method.

### BACKGROUND

Currently, millimeter waves have garnered widespread attention in the fields of communication and radar, becoming key technologies in both areas.

It is well known that communication chips or radar chips operating in the millimeter wave frequency band have relatively low output power. To further enhance system Effective Isotropic Radiated Power (EIRP), reception Signal-to-Noise Ratio (SNR), and the number of Multiple Input Multiple Output (MIMO) channels, it is common to use multiple chips for cascading local oscillators on a package or printed circuit board (PCB).

In the traditional cascading scheme of two chips with a common local oscillator, each chip requires two sets of signal pads to connect with two sets of matching networks to achieve the common local oscillator, such a requirement is not conducive to reducing chip area and cost.

It should be noted that the above introduction to the technical background aids in explanation of the technical solution and facilitating understanding by technical personnel in this field. The above technical solutions should not be considered as known to technical personnel in this field simply because they are described in this background section.

### SUMMARY

In view of the above-mentioned disadvantages of the related technology, the present disclosure aims to provide a common local oscillator chip, a cascading structure and a working method for solving problems of large memory area and high cost.

To achieve the above and other related purposes, the present disclosure provides a common local oscillator chip, including a local oscillator module, a driving module, a multiplexing matching network, a local oscillator selection module, an output matching network, and a multiplexing transmission port;
the local oscillator module is configured to provide an internal local oscillator signal;
the driving module is connected to the local oscillator module, and the driving module is configured to transmit the internal local oscillator signal when activated;
the multiplexing matching network is connected to the driving module, and the multiplexing matching network is configured to output the internal local oscillator signal through the multiplexing transmission port, or the multiplexing matching network is configured to receive an external local oscillator signal through the multiplexing transmission ports;
the local oscillator selection module is connected to the local oscillator module and the multiplexing matching network, the local oscillator selection module is configured to select one for output from the internal local oscillator signal and the external local oscillator signal, and the chip local oscillator signal is generated through the output matching network based on the internal local oscillator signal or the external local oscillator signal.

Optionally, the local oscillator module includes a phase-locked loop, a first buffer, and a second buffer, the phase-locked loop is configured to generate the internal local oscillator signal, and the first buffer and the second buffer are respectively connected to the phase-locked loop to output the internal local oscillator signal in two paths.

Optionally, the driving module includes a metal oxide semiconductor (MOS) transistor, a second MOS transistor, a third MOS transistor, and a fourth MOS transistor;
gates of the first MOS transistor and the second MOS transistor are connected to the local oscillator module, sources of the first MOS transistor and the second MOS transistor are connected to ground, a drain of the first MOS transistor is connected to a source of the third MOS transistor, and a drain of the second MOS transistor is connected to a source of the fourth MOS transistor;
a gate of the third MOS transistor is connected to a first bias voltage, a gate of the fourth MOS transistor is connected to a second bias voltage, and drains of the third MOS transistor and the fourth MOS transistor serve as output terminals of the driving module.

Optionally, the multiplexing matching network includes a first transformer, a first capacitor, and a second capacitor;
two ends of a first winding of the first transformer are respectively connected to the driving module and the local oscillator selection module, and the first capacitor is connected in parallel with the first winding of the first transformer;
a first end of a second winding of the first transformer is connected to the multiplexing transmission port, a second end of the second winding of the first transformer is connected to ground, and the second capacitor is connected in parallel with the second winding of the first transformer.

Optionally, the local oscillator selection module includes an internal local oscillator unit and an external local oscillator unit, the internal local oscillator unit includes a fifth MOS transistor, a sixth MOS transistor, a seventh MOS transistor, and an eighth MOS transistor, and the external local oscillator unit includes a ninth MOS transistor, a tenth MOS transistor, an eleventh MOS transistor, and a twelfth MOS transistor;
gates of the fifth MOS transistor and the sixth MOS transistor are connected to the local oscillator module, sources of the fifth MOS transistor and sixth MOS transistor are connected to ground, a drain of the fifth MOS transistor is connected to a source of the seventh MOS transistor, a drain of the sixth MOS transistor is connected to a source of the eighth MOS transistor;
gates of the ninth MOS transistor and the tenth MOS transistor are connected to the multiplexing matching network, sources of the ninth MOS transistor and the tenth MOS transistor are connected to ground, a drain of the ninth MOS transistor is connected to a source of the eleventh MOS transistor, and a drain of the tenth MOS transistor is connected to a source of the twelfth MOS transistor;
a gate of the seventh MOS transistor is connected to a third bias voltage, a gate of the eighth MOS transistor is connected to a fourth bias voltage, a gate of the eleventh MOS transistor is connected to a fifth bias voltage, a gate of the twelfth MOS transistor is connected to a sixth bias voltage, a drain of the seventh MOS transistor is connected to a drain of the eleventh MOS transistor, and a drain of the eighth MOS transistor is connected to a drain of the twelfth MOS transistor, serving as an output of the local oscillator selection module.

Optionally, the external local oscillator unit further comprises a third capacitor and a fourth capacitor, the gate of the ninth MOS transistor is respectively connected to the multiplexing matching network through the third capacitor, and the gate of the tenth MOS transistor is respectively connected to the multiplexing matching network through the fourth capacitor.

Optionally, the output matching network includes a second transformer, a fifth capacitor, and a sixth capacitor;
two ends of a first winding of the second transformer are connected to an output of the local oscillator selection module, and the fifth capacitor is connected in parallel with the first winding of the second transformer;
two ends of a second winding of the second transformer serve as output terminals of the output matching network, and the sixth capacitor is connected in parallel with the second winding of the second transformer.

The present disclosure further provides a cascading structure of common local oscillator chips, the cascading structure comprises two local oscillator chips as described above, and wherein multiplexing transmission ports of the local oscillator chips are interconnected.

Optionally, the multiplexing transmission ports of the common local oscillator chips are interconnected via an interconnection packaging structure or wirings on a PCB.

The present disclosure further provides a working method of the local oscillator chip as described above, the working method includes a normal mode, a master mode, and a slave mode;
in the normal mode, the driving module is off, and the oscillator selection module selects the internal oscillator signal;
in the master mode, the driving module is on, and the oscillator selection module selects the internal oscillator signal;
in the slave mode, the driving module is off, and the oscillator selection module selects the external oscillator signal.

As described above, the common local oscillator chip, the cascading structure, and the working method provided by the present disclosure achieve the multiplexing of signal ports and matching networks through the design of the local oscillator module, driving module, multiplexing matching network, local oscillator selection module, output matching network, and multiplexing transmission port; this allows for the cascading of two chips with a common local oscillator using only one signal port and the corresponding matching network, as a result, the chip has a compact area, minimal system overhead and therefore the design is beneficial for reducing costs and enhancing competitiveness.

### BRIEF DESCRIPTION OF THE DRAWINGS

FIG. 1 shows a schematic diagram of a cascading structure of a common local oscillator.

FIG. 2 shows a schematic diagram of a common local oscillator chip according to the present disclosure.

FIG. 3 shows a schematic diagram of a local oscillator module according to the present disclosure.

FIG. 4 shows a schematic diagram of a driving module, a multiplexing matching network, a local oscillator selection module and an output matching network according to the present disclosure.

FIG. 5 shows a schematic diagram of the common local oscillator chip working in a normal mode according to the present disclosure.

FIG. 6 shows a schematic diagram of the common local oscillator chip working in a master mode according to the present disclosure.

FIG. 7 shows a schematic diagram of the common local oscillator chip working in a slave mode according to the present disclosure.

FIG. 8 shows a schematic diagram of a cascading structure of common local oscillator chips according to the present disclosure.

### REFERENCE NUMERALS

100, 200 Common local oscillator chip
110, 210 Local oscillator module
211 Phase-locked loop
212 First buffer
213 Second buffer
120, 220 Driving module
130 First matching network
230 Multiplexing matching network
140, 240 Local oscillator selection module
241 Internal local oscillator unit
242 External local oscillator unit
150 Second matching network
160 Third matching network
250 Output matching network

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure

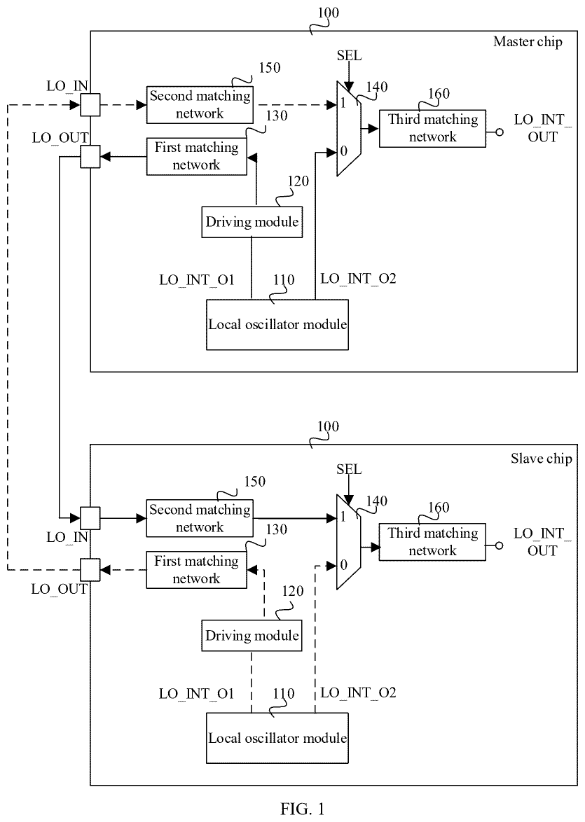

Refer to FIGS. 1-8. It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

FIG. 1 shows a schematic diagram of a cascading structure of local oscillators, the structures of two common local oscillator chips 100 are identical and each of the common local oscillator chips 100 includes a local oscillator module 110, a driving module 120, a first matching network 130, a local oscillator selection module 140, a second matching network 150, a third matching network 160, a local oscillator input terminal LO_IN, and a local oscillator output port LO_OUT; a first output of the local oscillator module 110 is connected to the local oscillator output port LO_OUT via the driving module 120 and the first matching network 130, a second output of the local oscillator module 110 is connected to the internal local oscillator input (terminal 0) of the local oscillator selection module 140; the external local oscillator input (terminal 1) of the local oscillator selection module 140 is connected to the local oscillator input port LO_IN via the second matching network 150, the output of the local oscillator selection module 140 is connected to the third matching network 160. The local oscillator input terminal LO_IN of the first common local oscillator chip 100 is interconnected with the local oscillator output port LO_OUT of the second common local oscillator chip 100, and the local oscillator output port LO_OUT of the first common local oscillator chip 100 is interconnected with the local oscillator input port LO_IN of the second common local oscillator chip 100.

Taking as an example the first common local oscillator chip 100 being a master chip and the second common local oscillator chip 100 being a slave chip, when achieving common local oscillation between the master chip and the slave chip, the local oscillator module 110 of the master chip provides two internal local oscillator signals. One signal passes through the local oscillator selection module 140 and the third matching network 160 to supply the local oscillator signal to the master chip. The other signal is output via the driving module 120 and the first matching network 130 to the local oscillator output port LO_OUT of the master chip, this signal then goes through the local oscillator input port LO_IN of the slave chip, the second matching network 150, the local oscillator selection module 140, and the third matching network 160 to provide the local oscillator signal to the slave chip.

In this common local oscillator cascading scheme, in order to achieve shared oscillation, both local oscillator chips 100 must be equipped with two signal ports (including the local oscillator input port LO_IN and the local oscillator output port LO_OUT) and the corresponding two matching networks (including the first matching network 130 and the second matching network 150). This requirement is not conducive to reducing the chip area and cost. To address this technical issue, the present disclosure further provides a more compact shared local oscillator cascading design that reduces chip area and cost by reusing signal ports and matching networks.

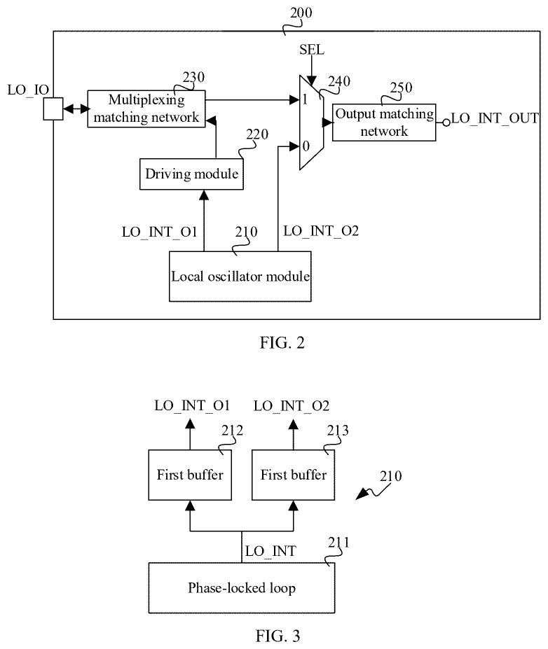

As shown in FIG. 2, the present disclosure provides a common local oscillator chip 200, the common local oscillator chip 200 includes a local oscillator module 210, a driving module 220, a multiplexing matching network 230, a local oscillator selection module 240, an output matching network 250, and a multiplexing transmission port LO_IO.

The local oscillator module 210 is used to provide an internal local oscillator signal LO_INT.

As an example, as shown in FIG. 3, the local oscillator providing module 210 includes a phase-locked loop 211, a first buffer 212, and a second buffer 213. The phase-locked loop 211 generates the internal local oscillator signal LO_INT, and the first buffer 212 and the second buffer 213 are connected to the phase-locked loop 211 to output the internal local oscillator signal LO_INT in two paths. Specifically, the first buffer 212 outputs one path of an internal local oscillator signal LO_INT_O1, and the second buffer 213 outputs the other path of an internal local oscillator signal LO_INT_O2.

The driving module 220 is connected to the local oscillator module 210 and said connection is used to transmit the internal local oscillator signal LO_INT when enabled. In practice, the driving module 220 is connected to the first buffer 212 in the local oscillator module 210 and transmits one path of the internal local oscillator signal LO_INT_O1 when enabled.

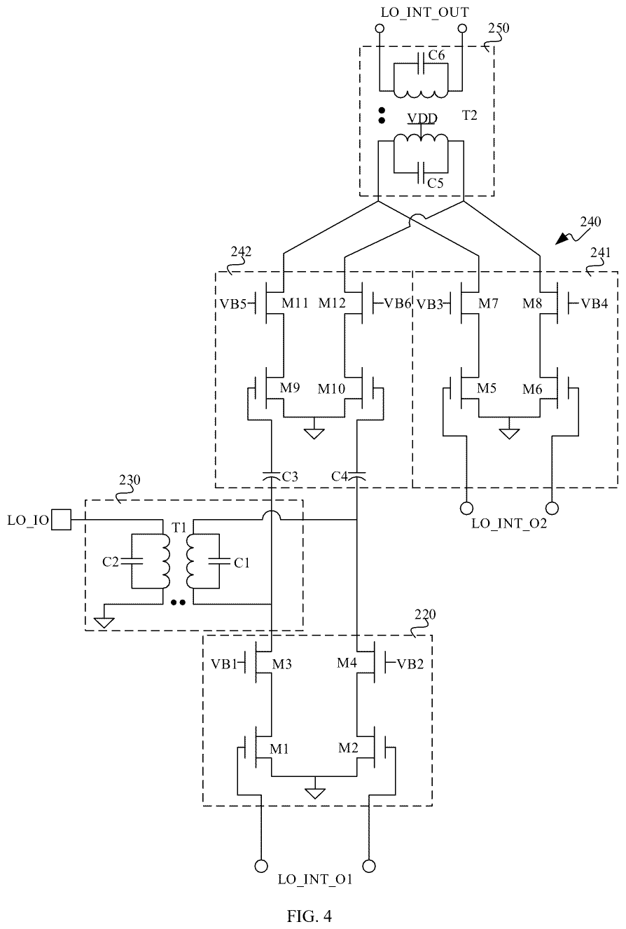

As an example, as shown in FIG. 4, the driving module 220 includes a first MOS transistor M1, a second MOS transistor M2, a third MOS transistor M3, and a fourth MOS transistor M4. Gates of the first MOS transistor M1 and the second MOS transistor M2 are connected to the local oscillator module 210 to receive one path of the internal local oscillator signal LO_INT_O1, sources of the first MOS transistor M1 and the second MOS transistor M2 are connected to ground. A drain of the first MOS transistor M1 is connected to a source of the third MOS transistor M3, and a drain of the second MOS transistor M2 is connected to a source of the fourth MOS transistor M4. A gate of the third MOS transistor M3 is connected to a first bias voltage VB1, a gate of the fourth MOS transistor M4 is connected to a second bias voltage VB2, and drains of the third MOS transistor M3 and the fourth MOS transistor M4 serve as the output terminals of the driving module 220.

In the driving module 220, the first MOS transistor M1, the second OS transistor M2, the third MOS transistor M3, and the fourth MOS transistor M4 form a common source common gate structure. By controlling the first bias voltage VB1 and the second bias voltage VB2, the activation of this common source common gate structure can be controlled, thereby determining whether the internal local oscillator signal LO_INT_O1 provided by the local oscillator module 210 is output to the multiplexing matching network 230 through the driving module 220.

The multiplexing matching network 230 is connected to the driving module 220 and said connection is used to output the internal local oscillator signal (such as one path of the internal local oscillator signal LO_INT_O1) through the multiplexing transmission port LO_IO, or to input an external local oscillator signal LO_EXT into the local oscillator selection module 240 via the multiplexing transmission port LO_IO. Additionally, the multiplexing matching network 230 is also used for input and output impedance matching.

As an example, as shown in FIG. 4, the multiplexing matching network 230 includes a first transformer T1, a first capacitor C1, and a second capacitor C2. The two ends of a first winding of the first transformer T1 are connected to the driving module 220 to receive one path of the internal local oscillator signal LO_INT_O1 and said two ends are connected to the local oscillator selection module 240 to output the external local oscillator signal LO_EXT. The first capacitor C1 is connected in parallel with the first winding of the first transformer T1; one end of a secondary winding of the first transformer T1 is connected to the multiplexing transmission port LO_IO to output one path of the internal local oscillator signal LO_INT_O1 or to input the external local oscillator signal LO_EXT, and the other end of the secondary winding of the first transformer T1 is connected to ground. The second capacitor C2 is connected in parallel with the secondary winding of the first transformer T1.

The local oscillator selection module 240 is connected to the local oscillator module 210 and the multiplexing matching network 230, said connection is used to select one path for output from the internal local oscillator signals (such as the other path of the internal local oscillator signal LO_INT_O2) and the external local oscillator signal LO_EXT, generating a chip local oscillator signal LO_INT_OUT through the output matching network 250. Additionally, the output matching network 250 is also used for output impedance matching.

As an example, as shown in FIG. 4, the local oscillator selection module 240 includes an internal local oscillator unit 241 and an external local oscillator unit 242. The internal local oscillator unit 241 includes a fifth MOS transistor M5, a sixth MOS transistor M6, a seventh MOS transistor M7, and an eighth MOS transistor M8, the external local oscillator unit 242 includes a ninth MOS transistor M9, a tenth MOS transistor M10, an eleventh MOS transistor M11, and a twelfth MOS transistor M12. Gates of the fifth MOS transistor M5 and the sixth MOS transistor M6 are connected to the local oscillator module 210 to receive the other path of the internal local oscillator signal LO_INT_O2, sources of the fifth MOS transistor M5 and the sixth MOS transistor M6 are connected to ground. A drain of the fifth MOS transistor M5 is connected to a source of the seventh MOS transistor M7, and a drain of the sixth MOS transistor M6 is connected to a source of the eighth MOS transistor M8. Gates of the ninth MOS transistor M9 and the tenth MOS transistor M10 are connected to the multiplexing matching network 230 to receive the external local oscillator signal LO_EXT, sources of the ninth MOS transistor M9 and the tenth MOS transistor M10 are connected to ground. A drain of the ninth MOS transistor M9 is connected to a source of the eleventh MOS transistor M11, and a drain terminal of the tenth MOS transistor M10 is connected to a source terminal of the twelfth MOS transistor M12. A gate of the seventh MOS transistor M7 is connected to a third bias voltage VB3, a gate of the eighth MOS transistor M8 is connected to a fourth bias voltage VB4, a gate of the eleventh MOS transistor M11 is connected to a fifth bias voltage VB5, and a gate of the twelfth MOS transistor M12 is connected to a sixth bias voltage VB6. A drain of the seventh MOS transistor M7 is connected to a drain of the eleventh MOS transistor M11, and drains of the eighth MOS transistor M8 is connected to a drain of the twelfth MOS transistor M12, serving as output terminals of the local oscillator selection module 240.

In the internal local oscillator unit 241, the fifth MOS transistor M5, the sixth MOS transistor M6, the seventh MOS transistor M7, and the eighth MOS transistor M8 form a common source common gate structure. By controlling the third bias voltage VB3 and the fourth bias voltage VB4, the activation of the common source common gate structure can be controlled, thereby determining whether the other path of the internal local oscillator signal LO_INT_O2 provided by the local oscillator module 210 is selected as an input for the local oscillator selection module 240.

Similarly, in the external local oscillator unit 242, the ninth MOS transistor M9, the tenth MOS transistor M10, the eleventh MOS transistor M11, and the twelfth MOS transistor M12 form a common source common gate structure. By controlling the fifth bias voltage VB5 and the sixth bias voltage VB6, the activation of the common source common gate structure can be controlled, thereby determining whether the external local oscillator signal LO_EXT provided by the multiplexing matching network 230 is selected as an input for the local oscillator selection module 240.

Furthermore, the external local oscillator unit 242 also includes a third capacitor C3 and a fourth capacitor C4. The gate of the ninth MOS transistor M9 is connected to the multiplexing matching network 230 via the third capacitor C3 and the gate of the tenth MOS transistor M10 is connected to the multiplexing matching network 230 via the fourth capacitor C4. The third capacitor C3 and the fourth capacitor C4 serve as AC coupling capacitors to block DC signals.

As an example, as shown in FIG. 4, the output matching network 250 includes a second transformer T2, a fifth capacitor C5, and a sixth capacitor C6. The two ends of a first winding of the second transformer T2 are connected to the local oscillator selection module 240 to receive the other path of the internal local oscillator signal LO_INT_O2 or the external local oscillator signal LO_EXT. The fifth capacitor C5 is connected in parallel with the first winding of the second transformer T2. Two ends of a secondary winding of the second transformer T2 serve as the output terminals of the output matching network 250 to output the chip local oscillator signal LO_INT_OUT, and the sixth capacitor C6 is connected in parallel with the secondary winding of the second transformer T2.

In practical applications, the common local oscillator chip 200 is a communication chip or a radar chip. The common local oscillator chip 200 also includes a main functional module (not shown in the figures) that is connected to the output matching network 250 and is used to perform main functions (such as communication functions, radar functions, etc.) based on the chip local oscillator signal LO_INT_OUT.

Correspondingly, the present disclosure also provides a working method for the common local oscillator chip 200 as described above, said method includes a normal mode, a master mode, and a slave mode.

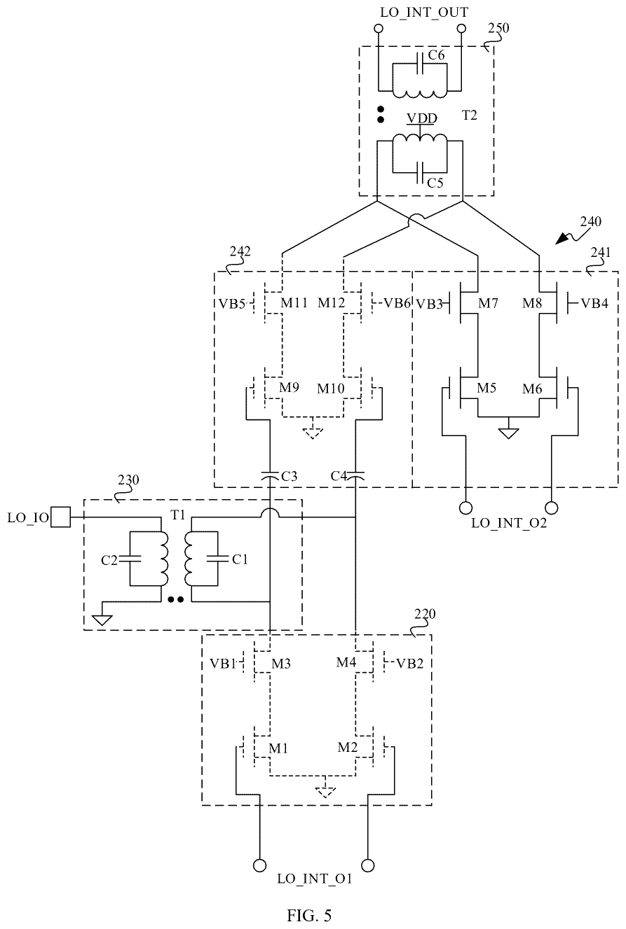

In the normal mode, as shown in FIG. 5, the driving module 220 is turned off, and the local oscillator selection module 240 selects the internal local oscillator signal (such as the other path of the internal local oscillator signal LO_INT_O2) as its input. At this point, the common local oscillator chip 200 cannot achieve shared oscillation with another common local oscillator chip 200 and only provides a local oscillator signal for itself.

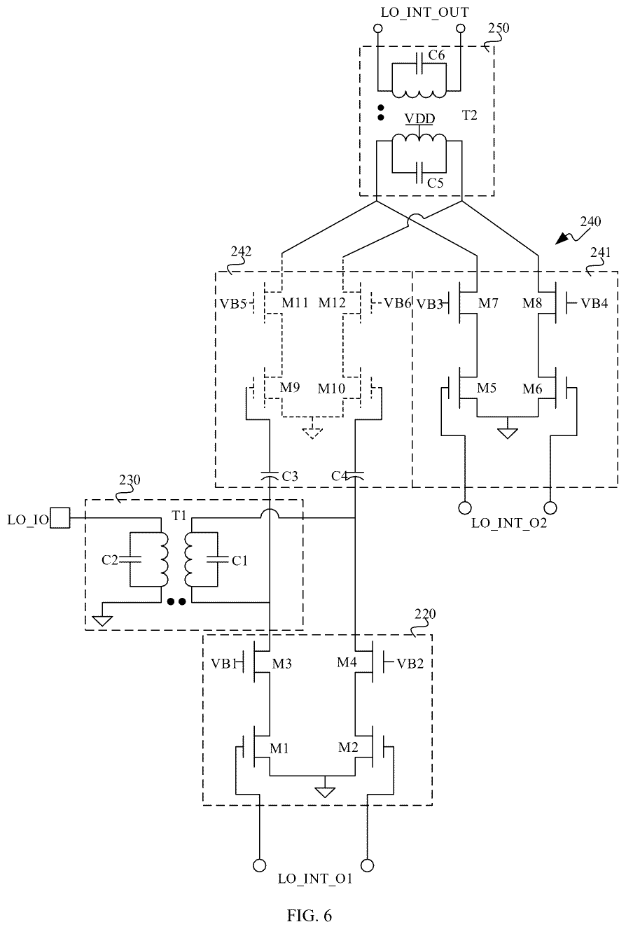

In the master mode, as shown in FIG. 6, the driving module 220 is turned on, and the local oscillator selection module 240 selects the internal local oscillator signal (such as the other path of the internal local oscillator signal LO_INT_O2) as its input. At this point, the common local oscillator chip 200 can achieve shared oscillation with another common local oscillator chip 200, with this common local oscillator chip 200 acting as the master chip, providing a local oscillator signal for itself and the other common local oscillator chip 200.

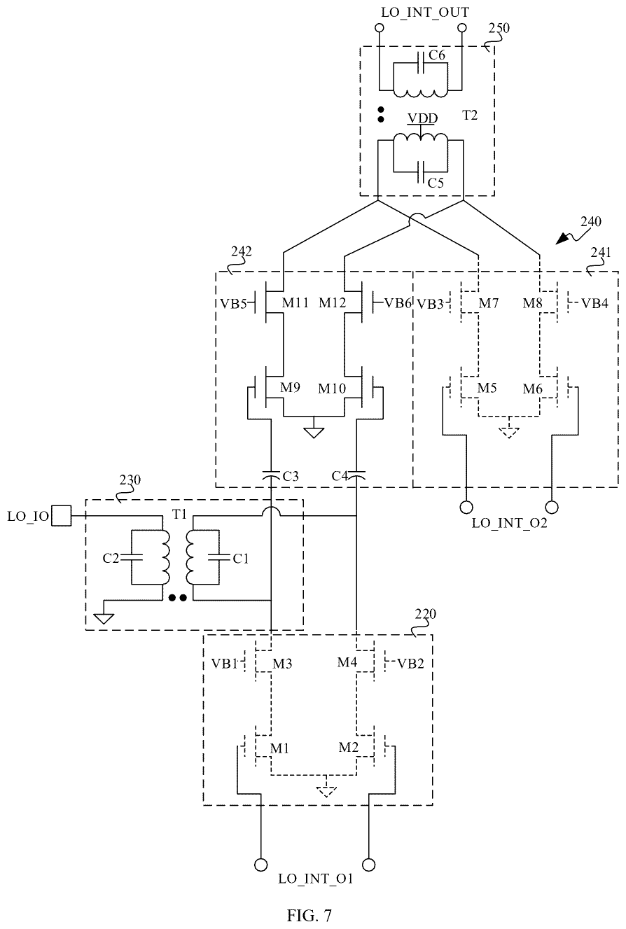

In the slave mode, as shown in FIG. 7, the driving module 220 is turned off, and the local oscillator selection module 240 selects the external local oscillator signal LO_EXT as its input. At this point, the common local oscillator chip 200 can achieve shared oscillation with another common local oscillator chip 200, with this common local oscillator chip 200 acting as the slave chip, receiving the local oscillator signal from the other common local oscillator chip 200.

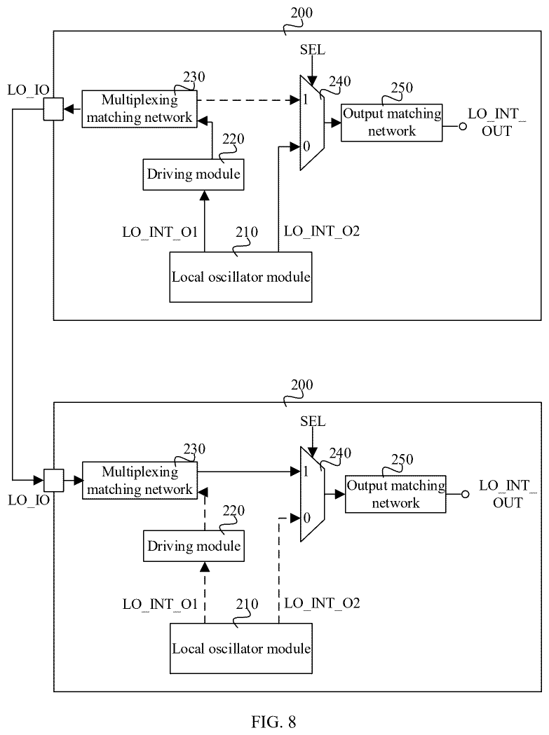

Correspondingly, as shown in FIG. 8, the present disclosure also provides a cascading structure of local oscillator chips, said structure includes two common local oscillator chips 200, each of which is as described above. Multiplexing transmission ports LO_IO of each common local oscillator chip 200 are interconnected. In practical applications, the multiplexing transmission ports LO_IO of each common local oscillator chip 200 are interconnected through packaging interconnection structures or PCB traces. When two cascaded common local oscillator chips 200 are in operation, there are three situations:

In the first situation, both common local oscillator chips 200 operate in the normal mode, meaning they cannot achieve shared oscillation and only provide local oscillator signals for themselves.

In the second situation, the first common local oscillator chip 200 operates in the master mode and acts as the master chip, and the second common local oscillator chip 200 operates in the slave mode and acts as the slave chip. At this point, the two common local oscillator chips 200 achieve shared oscillation, with the local oscillator signal provided by the first common local oscillator chip 200.

In the third situation, the first common local oscillator chip 200 operates in the slave mode and acts as the slave chip, and the second common local oscillator chip 200 operates in the master mode and acts as the master chip. At this point, the two common local oscillator chips 200 achieve shared oscillation, with the local oscillator signal provided by the second common local oscillator chip 200.

As described above, the local oscillator chip, the cascading structure, and the working method provided by the present disclosure achieve the multiplexing of signal ports and matching networks through the design of the local oscillator module, the driving module, the multiplexing matching network, the local oscillator selection module, the output matching network, and the multiplexing transmission port; this allows for the cascading of two chips with a common local oscillator using only one signal port and the corresponding matching network, as a result, the chip has a compact area, minimal system overhead and therefore, said design is beneficial for reducing costs and enhancing competitiveness. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A common local oscillator chip, comprising a local oscillator module, a driving module, a multiplexing matching network, a local oscillator selection module, an output matching network, and a multiplexing transmission port;
wherein the local oscillator module is configured to provide an internal local oscillator signal;
wherein the driving module is connected to the local oscillator module, and the driving module is configured to transmit the internal local oscillator signal when activated;
wherein the multiplexing matching network is connected to the driving module, and the multiplexing matching network is configured to output the internal local oscillator signal through the multiplexing transmission port, or the multiplexing matching network is configured to receive an external local oscillator signal through the multiplexing transmission ports;
wherein the local oscillator selection module is connected to the local oscillator module and the multiplexing matching network, the local oscillator selection module is configured to select one for output from the internal local oscillator signal and the external local oscillator signal, and the chip local oscillator signal is generated through the output matching network based on the internal local oscillator signal or the external local oscillator signal;
wherein the driving module comprises a first MOS transistor, a second MOS transistor, a third MOS transistor, and a fourth MOS transistor; and
wherein gates of the first MOS transistor and the second MOS transistor are connected to the local oscillator module, sources of the first MOS transistor and the second MOS transistor are connected to ground, a drain of the first MOS transistor is connected to a source of the third MOS transistor, and a drain of the second MOS transistor is connected to a source of the fourth MOS transistor; and
wherein a gate of the third MOS transistor is connected to a first bias voltage, a gate of the fourth MOS transistor is connected to a second bias voltage, and drains of the third MOS transistor and the fourth MOS transistor serve as output terminals of the driving module.

2. The common local oscillator chip according to claim 1, wherein the local oscillator module comprises a phase-locked loop, a first buffer, and a second buffer, wherein the phase-locked loop is configured to generate the internal local oscillator signal, and wherein the first buffer and the second buffer are respectively connected to the phase-locked loop to output the internal local oscillator signal in two paths.

3. The common local oscillator chip according to claim 1, wherein the multiplexing matching network comprises a first transformer, a first capacitor, and a second capacitor;
wherein two ends of a first winding of the first transformer are respectively connected to the driving module and the local oscillator selection module, and wherein the first capacitor is connected in parallel with the first winding of the first transformer;
wherein a first end of a second winding of the first transformer is connected to the multiplexing transmission port, a second end of the second winding of the first transformer is connected to ground, and wherein the second capacitor is connected in parallel with the second winding of the first transformer.

4. The common local oscillator chip according to claim 1, wherein the local oscillator selection module comprises an internal local oscillator unit and an external local oscillator unit, the internal local oscillator unit comprises a fifth MOS transistor, a sixth MOS transistor, a seventh MOS transistor, and an eighth MOS transistor, and wherein the external local oscillator unit comprises a ninth MOS transistor, a tenth MOS transistor, an eleventh MOS transistor, and a twelfth MOS transistor;
wherein gates of the fifth MOS transistor and the sixth MOS transistor are connected to the local oscillator module, sources of the fifth MOS transistor and sixth MOS transistor are connected to ground, a drain of the fifth MOS transistor is connected to a source of the seventh MOS transistor, and wherein a drain of the sixth MOS transistor is connected to a source of the eighth MOS transistor;
wherein gates of the ninth MOS transistor and the tenth MOS transistor are connected to the multiplexing matching network, sources of the ninth MOS transistor and the tenth MOS transistor are connected to ground, a drain of the ninth MOS transistor is connected to a source of the eleventh MOS transistor, and a drain of the tenth MOS transistor is connected to a source of the twelfth MOS transistor; and
wherein a gate of the seventh MOS transistor is connected to a third bias voltage, a gate of the eighth MOS transistor is connected to a fourth bias voltage, a gate of the eleventh MOS transistor is connected to a fifth bias voltage, a gate of the twelfth MOS transistor is connected to a sixth bias voltage, a drain of the seventh MOS transistor is connected to a drain of the eleventh MOS transistor, and wherein a drain of the eighth MOS transistor is connected to a drain of the twelfth MOS transistor, serving as an output of the local oscillator selection module.

5. The common local oscillator chip according to claim 4, wherein the external local oscillator unit further comprises a third capacitor and a fourth capacitor, wherein the gate of the ninth MOS transistor is respectively connected to the multiplexing matching network through the third capacitor, and wherein the gate of the tenth MOS transistor is respectively connected to the multiplexing matching network through the fourth capacitor.

6. The common local oscillator chip according to claim 1, wherein the output matching network comprises a second transformer, a fifth capacitor, and a sixth capacitor;
wherein two ends of a first winding of the second transformer are connected to an output of the local oscillator selection module, and wherein the fifth capacitor is connected in parallel with the first winding of the second transformer;
wherein two ends of a second winding of the second transformer serve as output terminals of the output matching network, and wherein the sixth capacitor is connected in parallel with the second winding of the second transformer.

7. A cascading structure of common local oscillator chips, wherein the cascading structure comprises two common local oscillator chips, each of which is a common local oscillator chip as described in claim 1, and wherein multiplexing transmission ports of the local oscillator chips are interconnected.

8. The cascading structure of common local oscillator chips according to claim 7, wherein the multiplexing transmission ports of the local oscillator chips are interconnected via an interconnection packaging structure or wirings on a PCB.

9. A working method of the common local oscillator chip as described in claim 1, wherein the working method comprises a normal mode, a master mode, and a slave mode;
wherein in the normal mode, the driving module is off, and the oscillator selection module selects the internal oscillator signal;
wherein in the master mode, the driving module is on, and the oscillator selection module selects the internal oscillator signal;
wherein in the slave mode, the driving module is off, and the oscillator selection module selects the external oscillator signal.
